(19) United States
(12) Patent Application Publication
(10) Pub. No.: US 2013/0093067 A1
(43) Pub. Date: Apr. 18, 2013

(54) WAFER LEVEL APPLIED RF SHIELDS

(71) Applicant: FLIPCHIP INTERNATIONAL, LLC, Phoenix, AZ (US)

(72) Inventors: David Clark, Ipswich (GB); Theodore G. Tessier, Chandler, AZ (US)

(73) Assignee: FLIPCHIP INTERNATIONAL, LLC, Phoenix, AZ (US)

(21) Appl. No.: 13/648,166

(22) Filed: Oct. 9, 2012

Related U.S. Application Data
(60) Provisional application No. 61/546,862, filed on Oct. 13, 2011.

(51) Int. Cl. H01L 23/552; H01L 21/98

(52) U.S. Cl. 257/659; 438/127; 257/E23.114; 257/E21.705

(57) ABSTRACT

An embodiment of a method of forming an on-chip RE shield on an integrated circuit chip in accordance with the present disclosure includes providing a wafer level integrated circuit component wafer having a front side and a back side before singulation; applying a resin metal layer on a back side of the wafer; and then separating the wafer into discrete RF shielded components. It is this resin metal layer on the back side that acts effectively as the RF shield, after singulation, i.e. separation of the wafer, into discrete RF shielded components.

### CROSS REFERENCE TO RELATED APPLICATIONS

This application claims the benefit of priority of U.S. Provisional Patent Application No. 61/546,862, filed Oct. 13, 2011, entitled Wafer Level Applied RF Shields, the disclosure of which is incorporated by reference herein in its entirety.

### FIELD

The present disclosure generally relates to formation of semiconductor chips and more particularly to a structure and method for the creation of on-chip RF shielding for active, passive or discrete components for embedded die packages.

### BACKGROUND

In certain electronic packaging applications, it is imperative to protect the device and system circuitry from sources of Electro-Magnetic Interference (EMI). It is also important to ensure that said device or system circuitry does not transmit EMI radiation to systems external to it. Hereby, ensuring the ability of such systems to operate as intended within a specific electromagnetic environment.

Spurious sources of EMI can lead to overall system or integrated circuit performance degradation, for example, through noise, cross talk and reduced signal-to-noise ratios. EMI is particularly problematic in mixed signal circuits.

EMI issues are typically solved by Radio Frequency (RF) shielding, whereby, the circuitry in question is capped by a dedicated metallic RF shield. A conductive and grounded shield (also known as a Faraday shield) between the EMI signal source and the system circuitry will eliminate this noise, by routing the EMI induced displacement currents directly to ground.

Such RF shields are normally mounted onto the system printed wiring board (PWB) by Surface Mount Technology (SMT) and may enclose a single or multiple components such as active, passive or discrete devices.

In embedded die packaging applications, RF shielding is particularly challenging. Use of traditional surface mounted RF shields may impose PWB routing design limitations and may impose keep out zones above or near EMI sensitive components.

In embedded die applications, it would be highly preferable if the PWB external surface area directly above the embedded component(s) was available for further component population and integration. It is not desirable to consume this valuable surface area real estate with low value add RF shielding components.

In some PWB designs, an entire PWB layer may be dedicated to provide a digital or analog ground plane thus providing further EMI protection to the component. Dedicating an entire PWB layer to EMI protection can be a costly solution and such a layer further inhibits routing to be placed in the EMI protected zone.

Surface mounted PWB, or other RF shields are typically connected to the system electrical ground plane through the existing PWB circuitry.

Surface mounted RF shields typically form the highest point on the PWB surface. Therefore the RF shield can often limit the total package or product thickness.

Surface mounted RF shields completely encapsulate sensitive components with contact to the PWB made around the periphery of the shield and thus tending to increase component or system footprint, In addition, surface mount RE shields can generate warpage of the overall chip package shape.

### SUMMARY OF THE DISCLOSURE

The method according to the present disclosure addresses the above noted deficiencies. One embodiment of a method of forming an on-chip RF shield on an integrated circuit chip in accordance with the present disclosure includes providing a wafer level integrated circuit component wafer having a front side and a back side before singulation; applying a resin metal layer on a back side of the wafer; and then separating the wafer into discrete RF shielded components. It is this resin metal layer on the back side that acts effectively as the RE shield for the components on the wafer. The resin metal layer preferably includes a metal foil and may also have a planar copper foil on an outer surface of the layer.

Another embodiment in accordance with the present disclosure is an integrated circuit chip cut from a wafer level integrated circuit component wafer having a front side and a back side and a resin metal layer formed on at least the back side of the wafer. The wafer may also have a resin metal layer over components on the front side of the wafer. The resin metal layer preferably includes a metal foil. This metal foil preferably is a copper foil on an outer surface thereof. The metal layer on the chip may be a resin copper foil (RCF) layer. In such an embodiment the RCF layer is a conductive paste applied on the back side of the wafer over at least one component on the wafer. This conductive paste may also be applied on the front side of the wafer over another component on the wafer.

### BRIEF DESCRIPTION OF THE DRAWINGS

For a more complete understanding of the present disclosure, reference is now made to the following figures in which:

FIG. 1 is a schematic cross sectional view of a typical EMI protected printed wiring board (PWB).

FIG. 2a is a schematic cross sectional view of an embeddable electronic integrated circuit component in accordance with the present disclosure.

FIG. 2b is a schematic cross section view of the electronic component shown in FIG. 2a in a wafer level chip scale package format in accordance with the present disclosure.

FIG. 3 is a schematic cross sectional view through an embedded chip packaging configuration in accordance with the present disclosure.

### DETAILED DESCRIPTION

This disclosure provides a low cost method for wafer level application of RF shielding for use in multiple electronic packaging formats and applications. This method is particularly useful in embedded die package applications to provide high yielding wafer level applied RF shielding.

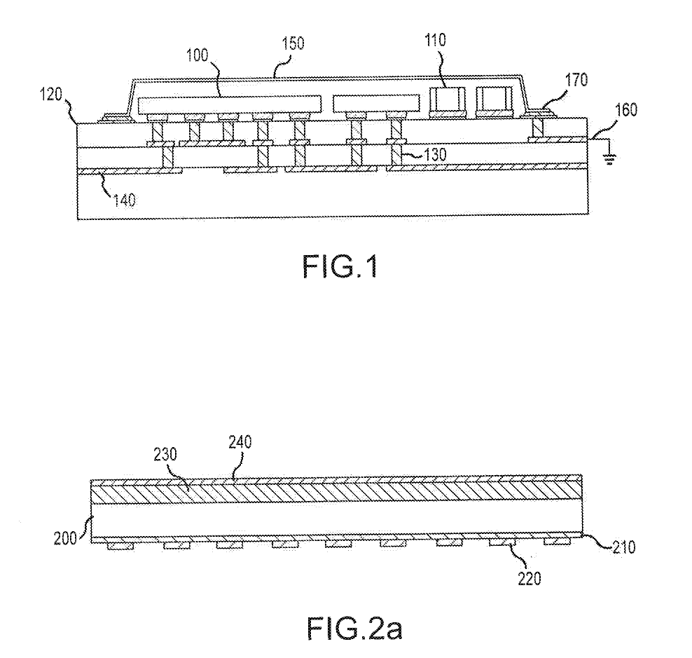

FIG. 1 illustrates a typical EMI shielding system on a printed wiring board (PWB). Single or multiple active and/or passive components 100 together with surface mounted discrete components 110 may be used to form an electronic system. The components are mounted on a typical printed circuit or wiring board 120. Electrical connectivity between the components is made using standard PWB through vias 130 and redistribution tracks 140. A typical SMT board mount RF shield 150 covers the system components and is connected through the PWB circuitry to electrical ground 160, The RF shield is typically either soldered or glued to the PWB around the periphery of the components 170

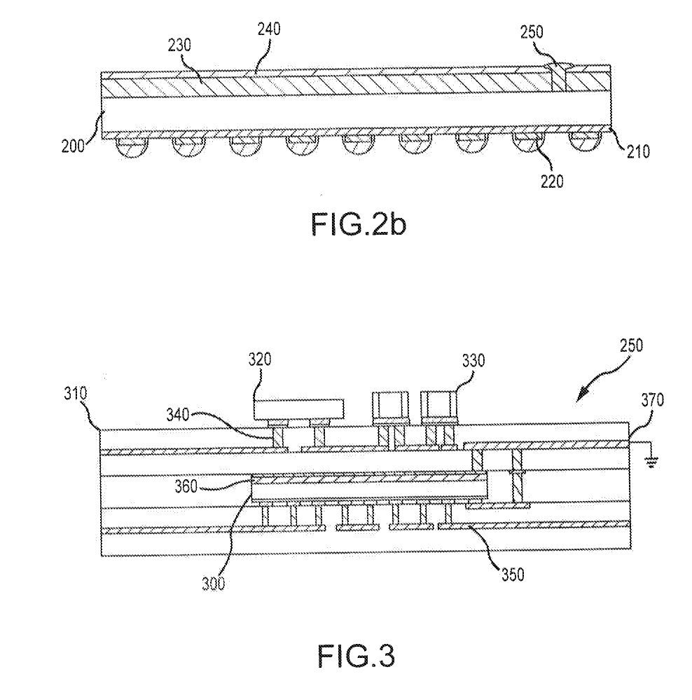

FIG. 2a illustrates an embeddable electronic integrated circuit component wafer 200 after wafer level fabrication and prior to singulation, i.e. before separation into discrete components in accordance with the present disclosure. The component wafer 200 includes a plurality of integrated circuit components and also contains integrated circuitry of the front side 210 with defined pads 220 for electronic connectivity to a printed wiring board. A layer of resin 230 with copper foil 240, called an RCF layer, is applied at wafer level thus forming an on-chip ready RF shield prior to device singulation.

The process in accordance with the present disclosure includes operations of (1) providing a wafer level component wafer prior to singulation from a wafer foundry; (2) applying a resin metal foil layer to at least the back side of the wafer thus forming a shielded wafer; (3) then separating the shielded wafer into discrete componentry. The foil layer is preferably copper. However other electrically conductive metals may alternatively be used such as gold, silver, silver alloy, or a copper alloy.

FIG. 2b illustrates an electronic component 200 in a wafer level chip scale package format with the wafer level applied RF shield formed on the component back side as in FIG. 2a. In the chip scale package (CSP) format shown, a copper paste filled through via 250 provides an electrical ground connection between the RF shield layer and the bulk semiconductor substrate.

FIG. 3 illustrates an embedded die package configuration 250 incorporating the EMI shielded component 300 produced as is shown in FIG, 2. Active, passive or discrete component(s) 300 as shown are embedded within the PWB substrate 310. The package 250 also has surface mounted active or passive ICs 320 and accompanying discrete components 330. Electrical connectivity between the embedded component 300 and surface mounted components 320 and 330 is made using conventional through vias 340 and redistribution lines 350. The embedded component 300 includes a backside RCF layer 360 forming the on-chip RF shielding. The on-chip RF shield is connected via existing PWB circuitry to the system ground plane 370.

A wafer level RF shield in accordance with the present disclosure can be used for a variety of wafer level RF shielding solutions, designs, thickness and geometries without adding significant process complexity or cost.

The EMI protective resin copper foil (RCF) layer may also be applied, in some applications, to the front side of the wafer level wafer to thus fully encapsulate the component. The ROE layer may utilize other metal alloys than copper which are also electrically conductive so as to provide RF shielding. Thus in accordance with the present disclosure, the individual component, after singulation, contains dedicated RF shielding features for use in localized EMI protection. The resin copper foil layer is used to conduct induced noise currents from EMI sources to the system electrical ground.

An RF shielded component constructed in accordance with the present disclosure is particularly applicable, but not limited to a variety of final component packaging formats, including flipchip packages, system-in-package, embedded die packages and other multi-die, multi-discrete 3D packages. This method is particularly desirable for embedded die packages.

The method described here-in improves component adhesion within embedded die packages and improves outgassing from the integrated circuit layers within embedded die applications. The RCF EMI shield layer maybe a conformal layer or pattern layer suitable for specific RF frequency filtering requirements. The resin layer may be chosen with a high-k material property to aid with reducing capacitively coupled EMI sources.

This method offers a lower cost solution compared to state-of-art electroplated on-chip alternatives and which can also aid with thermal dissipation. In addition the on-chip RF shield in accordance with the present disclosure eliminates potential overall package warpage that may otherwise occur with use of externally applied RF shields. Furthermore, the on-chip RF shield can be used in a surface mount configuration whereby the ground signal is provided by way of backside wirebond attach. All of these alternatives and features exemplify modifications that can be made which are within the meaning and broad scope of the disclosure and exemplified in the following claims.

1. A method of forming an on-chip RF shield on an integrated circuit chip comprising:
providing a wafer level integrated circuit component wafer having a front side and a back side;
applying a resin metal layer on at least a back side of the wafer; and
separating the wafer into discrete RF shielded components.

2. The method of claim 1 wherein the resin metal layer includes a metal foil thereon.

3. The method of claim 1 wherein the resin metal layer includes a planar copper foil on an outer surface thereof.

4. The method of claim 1 wherein the resin metal layer is selected from a group consisting of copper, gold, silver, gold alloy and copper alloy.

5. The method of claim 1 wherein the resin metal layer is applied as a paste.

6. An integrated circuit chip comprising:
a wafer level integrated circuit component wafer having a front side and a back side; and
a resin metal layer formed on at least the back side of the wafer.

7. The chip of claim 6 wherein the resin metal layer includes a metal foil.

8. The chip of claim 7 wherein the metal foil has a copper foil on an outer surface thereof.

9. The chip of claim 6 wherein the metal layer is a resin copper foil (RCF) layer.

10. The chip of claim 9 wherein the RCF layer is a paste on the back side of the wafer over at least one component on the wafer.
